(19) United States
(12) Patent Application Publication
(10) Pub. No.: US 2021/0366102 A1
(43) Pub. Date: Nov. 25, 2021

(54) INSPECTION APPARATUS OF WAFER

(71) Applicant: SAMSUNG ELECTRONICS CO., LTD., Suwon-si (KR)

(72) Inventors: Suhwan PARK, Incheon (KR); Namil Koo, Hwaseong-si (KR); Taeheung Ahn, Seoul (KR); Kwangjun Yoon, Suwon-si (KR); Jongmin Yoon, Incheon (KR); Ikseon Jeon, Suwon-si (KR); Jimin Choi, Suwon-si (KR)

(73) Assignee: SAMSUNG ELECTRONICS CO., LTD., Suwon-si (KR)

(21) Appl. No.: 17/102,700

(22) Filed: Nov. 24, 2020

(30) Foreign Application Priority Data
May 22, 2020 (KR) 10-2020-0061558

(51) Int. Cl. G06T 7/00; G01N 21/95; G01N 21/956; G06K 9/46; G06T 7/13; G06T 7/70; H01L 21/67

(52) U.S. Cl. CPC G06T 7/0004; G01N 21/9501; G01N 21/956; G06K 9/46; G06T 2207/30148; G06T 7/70; H01L 21/67288; G06K 2209/01; G06T 7/13

(57) ABSTRACT

An inspection apparatus includes a measurement device disposed to be spaced apart from an upper surface of a wafer, an image capturing device configured to capture an image of at least a portion of the measurement device and at least a portion of the upper surface of the wafer, a memory storing an algorithm to measure a distance between the measurement device and the upper surface of the wafer based on the image, and a controller configured to measure the distance between the measurement device and the upper surface of the wafer based on the algorithm, wherein the image includes a measurement region in which the measurement device is displayed, a wafer region in which the wafer is displayed, and a reflective region in which the measurement device being reflected on the upper surface of the wafer is displayed, and wherein the wafer region and the reflective region overlap with each other.

### CROSS-REFERENCE TO RELATED THE APPLICATION

This application claims priority to Korean Patent Application No. 10-2020-0061558 filed on May 22, 2020 in the Korean Intellectual Property Office, the disclosure of which is incorporated herein by reference in its entirety.

### BACKGROUND

Example embodiments of the present disclosure relate to an inspection apparatus of a wafer.

A semiconductor production line may include process chambers to perform various semiconductor processes. A chemical-mechanical polishing (CMP) process, a deposition process, an etching process, and the like, may be performed in the process chambers. When a semiconductor process is performed in each of the process chambers, a wafer on which the semiconductor process is performed may be inspected. A distance between a measurement device for inspection and a wafer needs to be accurately controlled to improve accuracy of wafer inspection.

### SUMMARY

Example embodiments provide an inspection apparatus configured to more accurately measure and adjust a distance between a measurement unit of a measurement device and an upper surface of a wafer to improve accuracy of wafer inspection.

According to an aspect of an example embodiment, there is provided an inspection apparatus including a measurement device disposed to be spaced apart from an upper surface of a wafer, an image capturing device configured to capture an image of at least a portion of the measurement device and at least a portion of the upper surface of the wafer, a memory storing an algorithm to measure a distance between the measurement device and the upper surface of the wafer based on the image, and a controller configured to measure the distance between the measurement device and the upper surface of the wafer based on the algorithm, wherein the image includes a measurement region in which the measurement device is displayed, a wafer region in which the wafer is displayed, and a reflective region in which the measurement device being reflected on the upper surface of the wafer is displayed, and wherein the wafer region and the reflective region overlap with each other.

According to another aspect of an example embodiment, there is provided an inspection apparatus including a probe disposed spaced apart from an upper surface of a wafer, an image capturing apparatus configured to capture an image of at least a portion of the probe and at least a portion of the upper surface of the wafer, a memory configured to store an algorithm to detect a location of the probe above the wafer based on the image, and a controller configured to detect the location of the probe above the wafer based on the image and the algorithm, wherein the image includes a first region in which the probe is displayed, a second region in which the wafer is displayed, and a third region in which the probe being reflected on the upper surface of the wafer is displayed, and wherein at least portions of the first region, the second region, and the third region overlap with each other on the image.

According to another aspect of an example embodiment, there is provided an inspection apparatus including a measurement device disposed above a measuring target, an image capturing device configured to capture an images of at least a portion of the measurement device and an upper surface of the measuring target in at least two locations, respectively, a memory storing an algorithm to measure a distance between the measurement device and the upper surface of the measuring target in the at least two locations based on the images, and a controller configured to measure the distance between the measurement device and the upper surface of the measuring target based on the algorithm and to detect a state of the upper surface of the measuring target in the at least two locations based on the measured distances, wherein each of the images includes a measurement region in which the measurement device is displayed, a measuring target region in which the measuring target is displayed, and a reflective region in which the measurement device being reflected on the upper surface of the measuring target is displayed, and wherein the measurement region and the reflective region overlap with each other.

### BRIEF DESCRIPTION OF DRAWINGS

The above and/or other aspects, features, and advantages of example disclosure will be more clearly understood from the following detailed description, taken in conjunction with the accompanying drawings.

FIG. 1 is a schematic configuration diagram of semiconductor process equipment including an inspection apparatus according to an example embodiment.

FIG. 2 is a schematic diagram of an inspection apparatus according to an example embodiment.

FIG. 3 is a block diagram of an inspection apparatus according to an example embodiment.

FIG. 4A illustrates an operation of an inspection apparatus according to an example embodiment.

FIG. 4B is an image obtained by an image capturing device in an inspection apparatus according to an example embodiment.

FIG. 5 is a flowchart illustrating a process of deriving a relational expression between the number of pixels and a distance in an inspection apparatus according to an example embodiment.

FIG. 6 illustrates a relational expression between the number of pixels and a distance in an inspection apparatus according to an example embodiment.

FIG. 7 is a flowchart illustrating a process of measuring a distance between a measurement unit and an upper surface of a wafer using pixels of an image, in an inspection apparatus according to an example embodiment.

FIG. 8 is a flowchart illustrating a process of detecting a location of a measurement unit on an upper surface of a wafer using pixels of an image, in an inspection apparatus according to an example embodiment.

FIG. 9A illustrates an operation of an inspection apparatus on a normal wafer having no tilt or warpage, in the inspection apparatus according to an example embodiment.

FIG. 9B illustrates an operation of an inspection apparatus when a wafer is tilted to have a tilt, in the inspection apparatus according to an example embodiment.

FIG. 9C illustrates an operation of an inspection apparatus according to an example embodiment when warpage occurs in a wafer, in the inspection apparatus.

FIG. 10 illustrates an image obtained by the operations of the inspection apparatus in FIGS. 9A to 9C, in the inspection apparatus according to an example embodiment.

FIG. 11 is a flowchart illustrating a process of detecting a tilt or warpage of a wafer, in an inspection apparatus according to an example embodiment.

FIG. 12 illustrates a process of detecting a tilt when a wafer has the tilt, in an inspection apparatus according to an example embodiment.

### DETAILED DESCRIPTION

Hereinafter, example embodiments will be described with reference to the accompanying drawings.

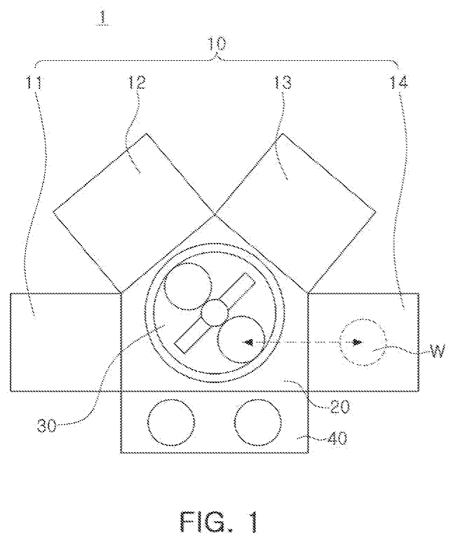

FIG. 1 is a schematic configuration diagram of semiconductor process equipment including an inspection apparatus according to an example embodiment.

Referring to FIG. 1, semiconductor processing equipment 1 according to an example embodiment may include a plurality of process chambers 11 to 14 in which semiconductor processes are performed. As an example, the plurality of process chambers 11 to 14 may include a deposition process chamber in which a deposition process is performed, a polishing process chamber in which a chemical-mechanical polishing (CMP) process is performed, an etching process chamber in which plasma including radicals and ions of a source gas is generated or at least a portion of element layers included in a wafer are removed using an etchant or the like, and the like. The plurality of process chambers may include an inspection process chamber, in which a wafer W is inspected, while a semiconductor process is performed or after the semiconductor process is finished.

As an example, the wafer W may be a semiconductor substrate including a semiconductor material. Semiconductor elements, interconnection patterns connected to the semiconductor elements, insulating layers covering the semiconductor elements and the interconnection patterns, and the like, may be formed on the wafer W by semiconductor processes performed in the plurality of process chambers 11 to 14, and a plurality of semiconductor chips may be produced from the wafer W.

As an example, the plurality of process chambers 11 to 14 may receive the wafer W through a transfer chamber 20 and a load-lock chamber 40 to perform a semiconductor process. The transfer chamber 20 and the load-lock chamber 40 may include a transfer robot 30. The transfer robot 30 of the transfer chamber 20 and the load-lock chamber 40 may transfer a wafer W, a process target. As an example, the transfer robot 30 of the transfer chamber 20 may take a process target, such as the wafer W, from the load-lock chamber 40 and may transfer the process target to the plurality of process chambers 11 to 14, and/or may transfer the process target between the plurality of process chambers 11 to 14. In an example embodiment, the transfer robot 30 may be a handler. The transfer robot 30 may include a chuck for fixing the process target, and a plurality of projections may be formed on an upper portion of the chuck to be in contact with the process target. The transfer robot 30 may further include a linear stage for transferring the process target.

Referring to FIG. 1, the transfer robot 30 of the transfer chamber 20 according to an example embodiment may take the wafer W from the load-lock chamber 40 and transfer the wafer W to the transfer chamber 20, and may transfer the wafer W, the process target, to the process chamber 14. According to example embodiments, the process target may not be limited to the wafer W. As an example, various substrates, other than the wafer W, such as a mother substrate for display may be provided as the process target.

In an example embodiment, the process chamber 14 may be an inspection process chamber for inspecting a processing status. The process chamber 14 may include a measurement device or an inspection apparatus for determining whether a semiconductor process has been properly performed, and various characteristics of the wafer W may be measured or inspected using the measurement device or the inspection apparatus. As an example, the process chamber 14 may be used to measure physical properties, sheet resistance, doping concentration, and the like of the wafer W. However, the process chamber 14 may be used to measure various other characteristics for determining whether the semiconductor process is properly performed.

Among the process chambers 11 to 14, at least one process chamber 14 may be allocated as a chamber to perform an inspection process, and the inspection process may be performed in an additional stage provided by the process chamber 14. However, embodiments are not limited thereto, and a measurement device or an inspection apparatus may be included in another semiconductor process chamber to perform the inspection process.

When the characteristics of the wafer W are not normally inspected during the inspection process, at least some of semiconductor elements formed on the wafer W may not operate normally. An error of alignment between the wafer W and the measurement device may occur. For example, the error of alignment may include a case in which the measurement device is not accurately disposed in a location of the wafer W to be inspected, a case in which a distance between a surface of the wafer W and the measurement device is not accurately controlled, or the like. As a result, when there is an error of alignment between the wafer W and the measurement device, at least some of the semiconductor elements formed on the wafer W may not operate normally. A displacement sensor may be used to measure the distance between the measurement device and the upper surface of the wafer W such that the measurement device may be disposed in an accurate location on the wafer W to be inspected and to prevent or reduce the error of alignment.

However, when a related displacement sensor is used, a wafer W may be tilted or warpage may occur in the wafer W. For this reason, an error may occur in a distance measured by the displacement sensor. When an error occurs in the distance measured by the displacement sensor, an error of alignment between the measurement device and the wafer W may not be sensed by the displacement sensor. As a result, an accurate inspection result may not be obtained in an inspection process.

The inspection apparatus according to an example embodiment may control a location of a measurement device using an image of a wafer W and the measurement device above the wafer W. The image may include not only the image of the wafer W and the measurement device, but also a reflected image in which the measurement device is reflected from the upper surface of the wafer W. As an example, the inspection apparatus may more accurately control the location of the measurement device based on the number of pixels between the measurement device and the reflected image in the image. Thus, the measurement device may be more accurately disposed in a location, in which an inspection process is to be performed on the wafer W, irrespective of a tilt or warpage of the upper surface of the wafer W.

The inspection apparatus according to an example embodiment may include a measurement device may perform an inspection process. However, embodiments are not limited thereto, and the inspection apparatus and the measurement device may be separate components. In addition, a device used in the inspection process is not limited to the measurement device and may be any specific device that may obtain data for inspecting the characteristics of the wafer W.

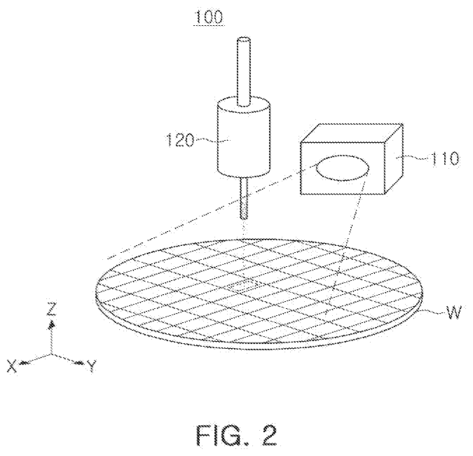

FIG. 2 is a schematic diagram of an inspection apparatus according to an example embodiment.

Referring to FIG. 2, an inspection apparatus 100 according to an example embodiment may include a measurement unit 120, may obtain a measurement value for inspecting characteristics of a wafer W in at least one location on the wafer W, and an image capturing device 110 may capture an image of the measurement unit 120, the wafer W, and the like.

The measurement unit 120 may be a component of the measurement device. As an example, the measurement unit 120 may include a probe. The measurement unit 120 may be spaced apart from the wafer W by a predetermined distance in a first direction (a Z direction), perpendicular to an upper surface of the wafer W. However, forms and functions of the measurement unit 120 are not limited by drawings and description. As an example, if a certain component needs to precisely align the distance to the wafer W and/or the position on the wafer W, the certain component may be regarded as a component corresponding to the measurement unit 120 according to an example embodiment. The measurement device may obtain measurement values for inspecting the characteristics of the wafer W, and the measurement unit 120 may determine the location of the wafer W to obtain the measurement values. The inspection apparatus 100 according to an example embodiment may inspect the characteristics of the wafer W using the obtained measurement value. The measurement unit 120 according to an example embodiment may be a measurement device for inspecting the wafer W.

The image capturing device 110 may be, for example, a camera. The image capturing device 110 may capture an image of the measurement unit 120 and the upper surface of the wafer W, and may capture an image such that at least a portion of each of the measurement unit 120 and the upper surface of the wafer W are include in a single image. The image capturing device 110 may capture an image at a predetermined angle to the upper surface of the wafer W. An angle between the image capturing device 110 and the upper surface of the wafer W may be determined by a tilt or warpage of the upper surface of the wafer W, or may be determined in advance as a predetermined value.

An image, obtained using the image capturing device 110, may be used to measure the distance between the measurement unit 120 and the upper surface of the wafer W. However, the use of the obtained image is not limited thereto, and the obtained image may be used to precisely align the measurement unit 120 and the wafer W according to example embodiments. In addition, according to example embodiments, when the measurement unit 120 is finely moved, the obtained image may be used to measure displacement of the measurement unit 120, or to measure the tilt or warpage of the wafer W.

The inspection apparatus 100 according to an example embodiment may appropriately align the measurement unit 120 and the wafer W depending on measurement reliability or spatial resolution required in the inspection process. The alignment may include an operation of controlling at least one of a distance between the measurement unit 120 and the upper surface of the wafer W in the first direction (Z-direction) and a location of the measurement unit 120 on a plane parallel to the upper surface of the wafer W (an X-Y plane).

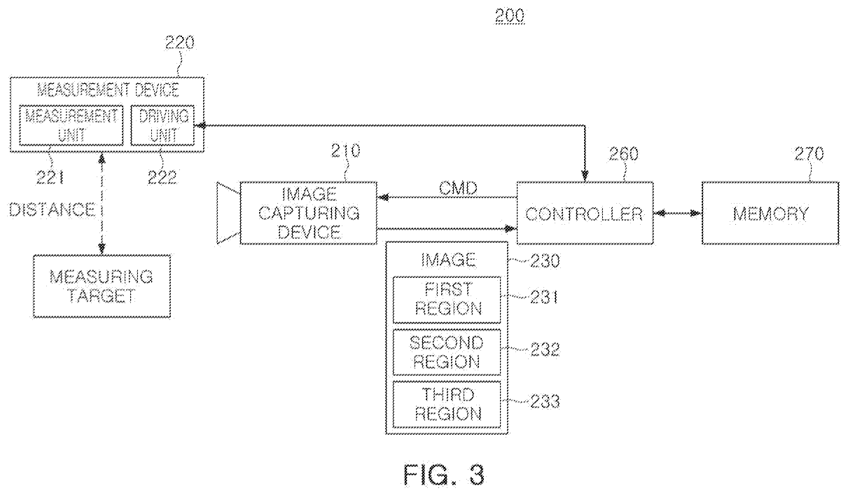

FIG. 3 is a block diagram of an inspection apparatus according to an example embodiment.

Referring to FIG. 3, an inspection apparatus 200 according to an example embodiment may include an image capturing device 210, a measurement device 220, a controller 260, a memory 270, and the like. The measurement device 220 may include a measurement unit 221 and a driving unit 222. The controller 260 may include at least one processor formed of hardware and/or software modules configured to perform corresponding functions described herein. The measurement unit 221 may also include at least one processor formed of hardware and/or software modules configured to perform corresponding functions described herein. The driving unit 222 may include at least one motor and at least one processor formed of hardware and/or software modules configured to perform corresponding functions described herein. The measurement unit 221 may obtain measurement values for inspecting characteristics of a measuring target 250, and may be spaced apart from an upper surface of the measuring target 250 by a predetermined distance. In an example embodiment, the measuring target 250 may be a wafer.

In the inspection apparatus 200 according to an example embodiment, the driving unit 222 may move at least one of the measurement unit 221 and the measuring target 250 in response to a control command received from the controller 260. As an example, the driving unit 222 may move at least one of the measurement unit 221 and the measuring target 250 in a plurality of directions to align the measurement unit 221 and the measuring target 250. According to example embodiments, the driving unit 222 may be provided separately from the measurement device 220.

In the inspection apparatus 200 according to an example embodiment, the image capturing device 210 may capture an image of the measurement unit 221 and the measuring target 250 to obtain an image 230. The image 230, obtained by the image capturing device 210, may include a first region 231 in which at least a portion of the measurement unit 221 is displayed, a second region 232 in which at least a portion of the measuring target 250 is displayed, and the like. Also the image 230, obtained by the image capturing device 210, may include a third region 233 in which at least a portion the measurement unit 221 being reflected on an upper surface of the measuring target 250 is displayed. As an example, the third region 233 may overlap the second region 232.

For example, the first region 231 may be defined as a measurement region including an image of the measurement unit 221, and the second region 232 may be defined as a measuring target region including an image of the measuring target 250. The third region 233, in which the measurement unit 221 being reflected from the upper surface of the measuring target 250 is displayed, may be a reflective region. In an example embodiment, the measurement region may include at least one feature region serving as a reference for measuring a distance between the measurement unit 221 and the upper surface of the measuring target 250.

In the inspection apparatus 200 according to an example embodiment, the controller 260 may apply an algorithm for detecting a feature region to the captured image 230 and may measure a distance between the measurement unit 221 and the upper surface of the measuring target 250 using the detected feature region. As an example, the controller 260 may determine a first feature region appearing in the first region 231 of the image 230 and a second feature region appearing in the third region 233 of the image 230 to measure a distance, and may detect the number of pixels included between the first feature region and the second feature regions. The second feature region may be a region in which the first feature region is reflected from the upper surface of the measuring target 250 to appear. The controller 260 may measure an actual distance using the detected number of pixels and a predetermined relational express obtained in advance.

The algorithm, used by the controller 260, the relational expression, and the like, may be stored in the memory 270. As an example, the algorithm stored in the memory 270 may be used to detect a feature region in the image 230 obtained using the image capturing device 210. In addition, the relational expression stored in the memory 270 may be used to measure the distance between the measurement unit 221 and the upper surface of the measuring target 250.

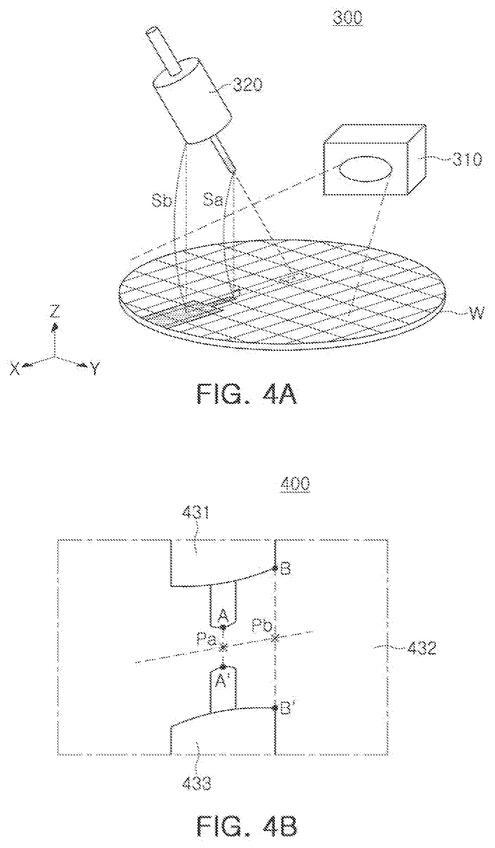

FIG. 4A illustrates an operation of an inspection apparatus according to an example embodiment, and FIG. 4B is an image obtained by an image capturing device in an inspection apparatus according to an example embodiment.

Referring to FIG. 4A, an upper surface of a wafer W, inspected by an inspection apparatus 300 according to an example embodiment, may be mirror-treated in a polishing process. As an example, an image captured by an image capturing device 310 may include an image in which a measurement unit 320 is reflected from the mirror-treated surface of the wafer W. The wafer W may be a reference surface on which the inspection apparatus 300 according to an example embodiment operates.

The image capturing device 310, which may be included in the inspection apparatus 300 according to an example embodiment, may capture an image of the measurement unit 320 and the wafer W to measure distances Sa and Sb between the measurement unit 320 and the wafer W. As an example, the distances Sa and Sb between the measurement unit 320 and the wafer W may be vertical distances between at least one feature region, included in the measurement unit 320, and the upper surface of the wafer W.

Referring to FIG. 4B, an image 400 obtained by an image capturing device included in an inspection apparatus according to an example embodiment may include a measurement region 431 in which a measurement unit is displayed, a wafer region 432 in which a wafer is displayed, a reflective region 433 in which the measurement unit being reflected on an upper surface of the wafer is displayed, and the like.

In the inspection apparatus according to the embodiment, the measurement region 431 included in the image 400 may include one or more first feature regions A and B, a reference for measuring a distance between a measurement unit 320 and an upper surface of a wafer W. In an example embodiment, the first feature regions A and B are illustrated as end portions or corner portions of the measurement region 431, but embodiments are not limited to such a form. As an example, the first feature regions A and B may be not only be a boundary region of an end portion, a corner portion, and the like of the measurement region 431 but also a region of at least a portion included in the measurement region 431. In addition, the first feature regions A and B may have one form among a point, a line, and a surface. As an example, a plurality of first feature regions A and B may be defined and, among the plurality of first feature regions A and B, some feature regions A and B may have different shapes. The reflective region 433 may include second feature regions A′ and B′ corresponding to the first feature regions A and B included in the measurement region 431.

However, in an actual measurement unit, locations of the first feature regions A and B and locations of second feature regions A′ and B′ may be different from each other in each image 400 depending on a location of the image capturing device or the measurement unit even when they correspond to the same region. Accordingly, the inspection apparatus according to an example embodiment may use at least one of algorithms such as a pattern matching algorithm, an edge detection algorithm, and an optical character recognition (OCR) algorithm to detect the first feature regions A and B in the measurement region 431, irrespective of the location of the image capturing device or the measurement unit.

When the pattern matching algorithm is used, a determination may be made as to determine whether a specific pattern related to a feature region appears in an image, different from an image in which the feature region is detected, and where the feature region appears. As an example, the pattern matching algorithm may be efficiently used when a large amount of images are treated. When the edge detection algorithm is used, a portion having a large change in contrast may be detected as a boundary line using contrast of an image. As an example, the edge detection algorithm may be efficiently used when the feature region is located along the contour of a measurement region, and may find a pixel corresponding to an edge in another image. When the OCR algorithm is used, an obtained image may be converted into a machine-readable character to detect a position, corresponding to a first feature region of an existing image, in another image. At least one of the algorithms may be appropriately selected and used according to a measurement device or a wafer.

In the inspection apparatus according to an example embodiment, a distance between a measurement unit and an upper surface of a wafer may be measured using the number of pixels between first feature regions A and B and second feature regions A′ and B′ on the image 400. For example, a value obtained by dividing the number of pixels between the first feature regions A and B and the second feature regions A′ and B′ by 2 may correspond to the distance between the measurement unit and the upper surface of the wafer.

The upper surface of the wafer, a reference surface of the actual distance, may not directly appear on the image 400. As an example, since the reflective region 433 is an image in which the measurement region 431 is reflected on the upper surface of the wafer, the first feature regions A and B and the second feature regions A′ and B′ may be symmetrical to each other with respect to a virtual axis parallel to the upper surface of the wafer. The virtual axis may be an axis of symmetry and may be one of axes present on the upper surface of the wafer.

In the measurement region 431 and the reflective region 433, midpoints Pa and Pb of imaginary lines, connecting the first feature regions A and B and the second feature regions A′ and B′, respectively, may each be a point on the upper surface of the wafer. For example, the midpoint Pa may be a midpoint of the first feature region A and second feature region A′, and the midpoint Pb may be a midpoint of the first feature region B and the second feature region B′. Accordingly, the midpoints Pa and Pb may be points through which an axis of symmetry passes, and the axis of symmetry may be determined when at least two midpoints Pa and Pb are defined. As an example, a direction of the axis of symmetry may vary depending on a location of the image capturing device and the wafer, a viewing angle of the image capturing device, and an angle at which the image capturing device captures an image of the wafer.

For example, the number of pixels between the first feature region A and B and the midpoint Pa and Pb may be the same as a value obtained by dividing the number of pixels between the first feature region A and B and the second feature region A′ and B′ by 2. The number of pixels between the first feature regions A and B and the midpoints Pa and Pb may correspond to the distance between the measurement unit and the upper surface of the wafer.

The inspection apparatus according to an example embodiment may obtain a relational expression between an actual distance and the number of pixels under corresponding conditions in advance to measure the measure a distance between the measurement unit and the upper surface of the wafer using the first feature region A and B and the second feature region A′ and B′, irrespective of the location of the image capturing device or the measurement unit. The distance between the measurement unit and the upper surface of the wafer may be measured from the number of pixels between the first feature regions A and B and the second feature regions A′ and B′ of the image, based on a predetermined relational expression.

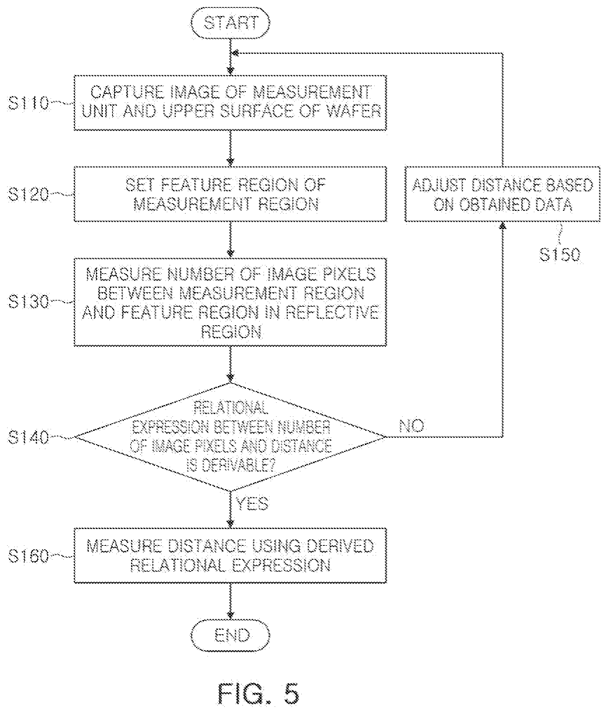

FIG. 5 is a flowchart illustrating a process of deriving a relational expression between the number of pixels and a distance in an inspection apparatus according to an example embodiment.

Referring to FIG. 5, an inspection apparatus according to an example embodiment may capture an image of a measurement unit and an upper surface of a wafer using an image capturing device to generate a data set for deriving a relational expression between the number of pixels and a distance (S110). The capturing an image performed in operation S110 may have characteristics similar to those of capturing an image performed to measure the distance between the measurement unit and the upper surface of the wafer according to the example embodiment of FIG. 4A.

The image obtained in operation S110 may correspond to the image according to the example embodiment illustrated in FIG. 4B. Therefore, referring to FIG. 5 together with FIG. 4A, the image obtained in operation S110 may include a measurement region 431, a wafer region 432, and a reflective region 433. As an example, first feature regions A and B of a measurement region 431, a reference for measuring a distance, may be set in the obtained image (S120). The inspection apparatus may measure the number of pixels between the first feature regions A and B of the measurement region 431 and the second feature regions A′ and B′ of the reflective region 433, respectively, as a piece of data included in the generated data set (S130).

The number of pixels, measured in operation S130, may be used as work data to derive a predetermined relational expression. The inspection apparatus according to an example embodiment may determine whether a relational expression between the number of pixels and an actual distance is derivable based on the obtained data (S140).

When the relational expression between the number of pixels and the actual distance cannot be derived in operation S140, the distance may be adjusted by moving at least one of the measurement unit and the wafer based on data obtained up to that point in time (S150). For example, the adjusting of the distance may be performed by a driving unit. The inspection apparatus according to an example embodiment may change an alignment of the measurement unit and the wafer in operation S150 and then may repeatedly perform operation S110 to operation S140 to obtain data on a relationship between the number of pixels and the actual distance. As an example, a relationship between the actual distance adjusted in operation S150 and a change in the number of pixels may be derived based on the data obtained after the adjustment. When operation S120, in which the feature region of the measurement unit is reset, is performed after operation S150, the same feature region may be set in different images using one of the above-described algorithms such as the pattern matching algorithm, the edge detection algorithm, and the optical character recognition (OCR) algorithm.

When the relationship between the number of pixels and the actual distance can be derived in operation S140, the actual distance between the measurement unit and the upper surface of the wafer upper may be measured from the number of detected pixels using the derived relationship (S160).

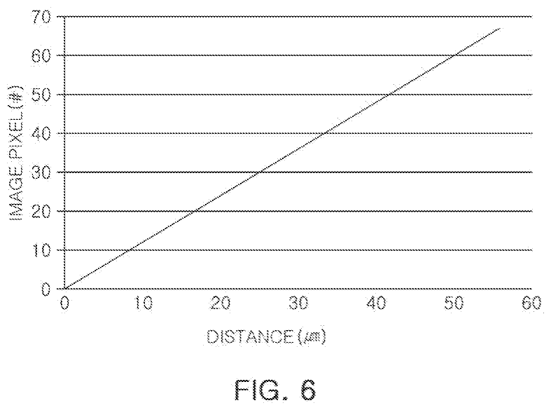

FIG. 6 illustrates a relational expression between the number of pixels and a distance in an inspection apparatus according to an example embodiment.

The inspection apparatus according to an example embodiment may derive a relational expression between the number of pixels of the obtained image and the actual distance by operations S110 to S160 described in the flowchart of FIG. 5. Referring to FIG. 6, there may be a linear relationship between the number of pixels and a distance. As an example, a slope of a graph may vary depending on an angle between the image capturing device and the measurement unit, but linearity may be maintained.

For example, when the angle between the image capturing device and the measurement unit is reduced, the number of pixels of an image to the actual distance may be decreased and the slope of the graph may also be decreased. However, even when the slope of the graph is decreased, linearity of the graph may be maintained because the number of pixels at the same distance is the same for the same angle. Accordingly, even when the angle between the image capturing device and the measurement unit is changed, the distance between the measurement unit and the upper surface of the wafer may be precisely measured based on the data set on the number and distance of the pixels having a linear relationship.

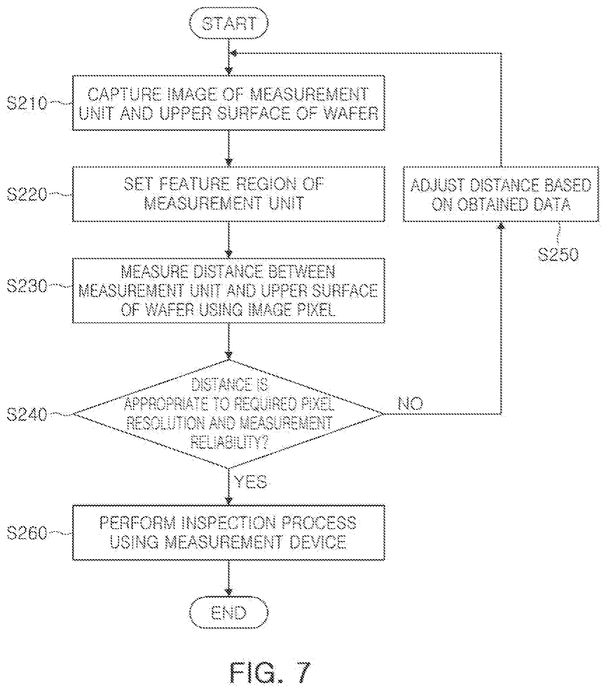

FIG. 7 is a flowchart illustrating a process of measuring a distance between a measurement unit and an upper surface of a wafer using pixels of an image, in an inspection apparatus according to an example embodiment.

Referring to FIG. 7, an inspection apparatus according to an example embodiment may derive a relational expression between the number of pixels and a distance, and then may capture an image of a measurement unit and an upper surface of a wafer using an image capturing device to measure a distance between the measurement unit and the upper surface of the wafer (S210).

The image obtained in operation S210 may correspond to the image illustrated in FIG. 4B. Accordingly, referring to FIG. 7 together with FIG. 4B, the image obtained in operation S210 may include a measurement region 431, a wafer region 432, and a reflective region 433. Then, first feature regions A and B of the measurement region 431, a reference for measuring a distance in the obtained image, may be set (S220).

The distance between the measurement unit and the upper surface of the wafer may be measured using a predetermined relational expression between the number of pixels and a distance. As an example, the number of pixels between the first feature regions A and B of the measurement region 431 and the second feature regions A′ and B′ of the reflective region 433, respectively, may be detected. The distance between the measurement unit and the upper surface of the wafer may be measured by applying the measured number of pixels to the predetermined relational expression (S230).

The inspection apparatus according to an example embodiment may determine whether the distance measured in operation S230 is a distance appropriate to spatial resolution and measurement reliability required by a corresponding measurement device and a corresponding wafer (S240). When it is determined that the distance is not appropriate to the spatial resolution and measurement reliability required by the measurement device and the wafer in operation S240, the distance is adjusted by moving at least one of the measurement unit or the wafer (S250).

For example, when a high measurement reliability and high spatial resolution are required in the inspection process, the inspection apparatus according to an example embodiment may align the measurement unit and the wafer such that the distance between the measurement unit and the upper surface of the wafer is shorter than that when a high measurement reliability and high spatial resolution are not required. As an example, the alignment may be performed by a driving unit. Therefore, displacement of the measurement unit needs to be more precisely measured such that the measurement unit and the wafer are aligned to be appropriate to the required spatial resolution.

On the other hand, when it is determined that the measured distance corresponds to a distance appropriate to the spatial resolution and measurement reliability required by the measurement device and the wafer in operation S240, the inspection may be continuously performed using the measurement device (S260).

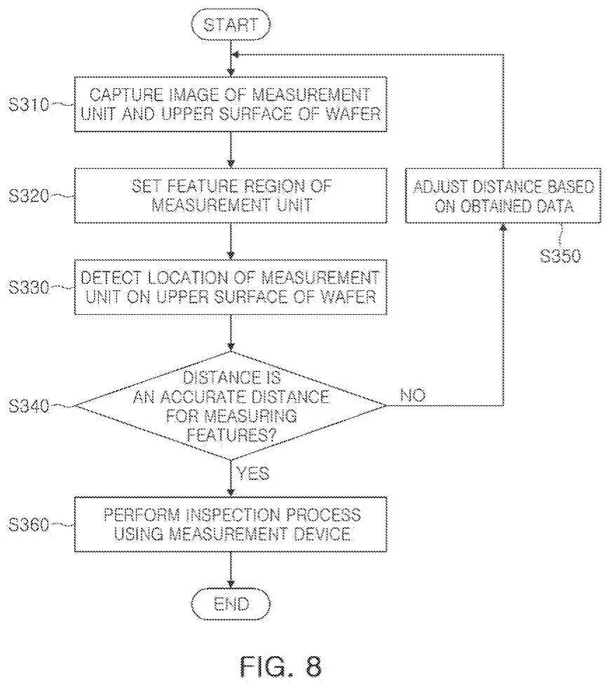

FIG. 8 is a flowchart illustrating a process of detecting a location of a measurement unit on an upper surface of a wafer using pixels of an image, in an inspection apparatus according to an example embodiment.

Referring to FIG. 8, the inspection apparatus may capture an image including an measurement unit reflected on an upper surface of a wafer to measure a distance between the measurement unit and the upper surface of wafer upper surface and to detect a point on the upper surface of the wafer in which the measurement unit is disposed. Therefore, an inspection process may be performed after an accurate location of the measurement unit is detected using the inspection apparatus according to an example embodiment.

Similar to measurement of the distance between the measurement unit and the upper surface of the wafer, an image of the measurement unit and the upper surface of the wafer may be captured using an image capturing device (S310). A feature region of the measurement unit, a reference for measuring a distance, may be set in the captured image (S320). Then, a point on the upper surface of the wafer, in which the measurement unit is disposed, may be detected (S330). For example, referring to FIG. 8 together with FIG. 4B, the inspection apparatus according to an example embodiment may detect midpoints Pa and Pb of a virtual line connecting the first feature regions A and B of the measurement region 431 and the second feature regions A′ and B′ of the reflective region 433, respectively. As an example, the midpoints Pa and Pb may be points on the upper surface of the wafer in which the measurement unit is disposed.

The inspection apparatus according to an example embodiment may detect whether the point detected in operation S330 is an accurate location of the wafer in which a measurement value is to be obtained using the measurement device (S340). For example, when measurement having high measurement reliability is required, a criterion of determining whether the point is an accurate location in operation S330 may be relatively stricter because it is necessary to accurately locate the measurement unit in a point to be measured.

When the detected point is not the accurate position of the wafer in which characteristics are to be measured using the measurement device, the position may be adjusted by moving at least one of the measurement unit and the wafer (S350). On the other hand, when the detected point is the accurate position of the wafer in which characteristics are to be measured using the measurement device, the inspection may be continuously performed using the measurement device (S360). As an example, the adjustment may be performed by a driving unit.

The operation of detecting the point on the upper surface of the wafer, in which the measurement unit is disposed, by the inspection apparatus according to an example embodiment, illustrated in the flowchart of FIG. 8, may be performed separately from the distance measurement operation according to the example embodiment of FIG. 7. However, embodiments are not limited thereto, and the operation of detecting the point on the upper surface of the wafer, in which the measurement unit is disposed, and the operation of the inspection apparatus for measuring the distance between the measurement unit and the upper surface of the wafer may be simultaneously performed to improve the precision of the inspection process.

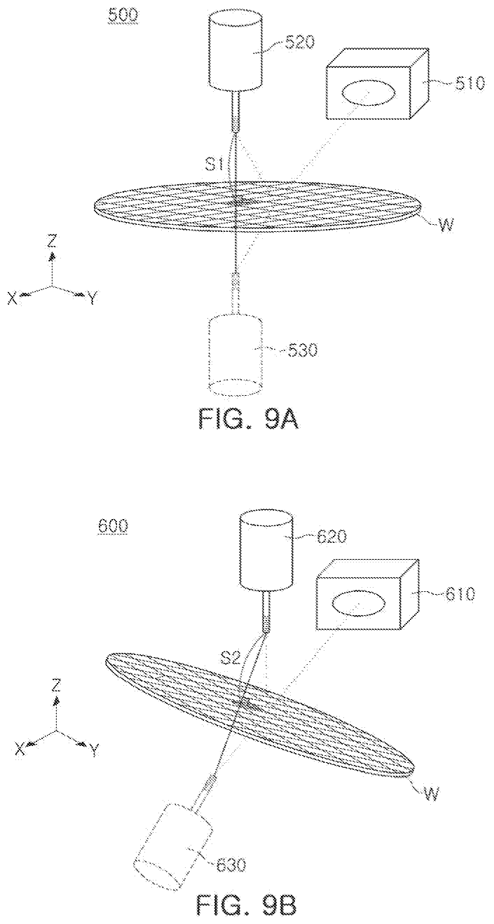

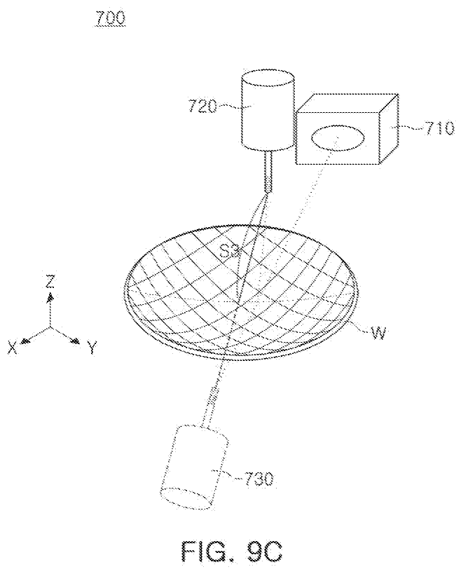

FIG. 9A illustrates an operation of an inspection apparatus on a normal wafer having no tilt or warpage, in the inspection apparatus according to an example embodiment, and FIGS. 9B and 9C illustrates an operation of an inspection apparatus when a wafer is tilted to have a tilt and when warpage occurs in a wafer, in the inspection apparatus, respectively.

Referring to FIGS. 9A to 9C, the inspection apparatuses 500, 600, and 700 according to an example embodiment may precisely measure distance S1, S2, and S3 between the measurement unit 520, 620, and 720 and the upper surface of the wafer W even when the wafer W is tilted or warpage is present in the wafer W, respectively. As an example, the inspection apparatus 500, 600, 700 may precisely measure a distance to a degree of several micrometers, but the precision of the measurement may vary depending on measurement environments. The inspection apparatus 500, 600, and 700 according to an example embodiment may perform the operations illustrated in the flowcharts of FIGS. 5 and 7 to measure distances S1, S2, and S3 between the measurement unit 520, 620, and 720 and the upper surface of the wafer W.

Referring to FIG. 9A, in the inspection apparatus 500 according to an example embodiment, the image capturing device 510 may capture an image including at least a portion of the measurement unit 520 and at least a portion of the wafer W. An image 530, in which the measurement unit 520 is reflected on the upper surface of the wafer W, may overlap at least a portion of the wafer W included in the image generated by the image capturing device 510. As an example, the measurement unit 520 and the image 530, in which the measurement unit 520 is reflected on the upper surface of the wafer W, may be symmetrical to each other based on a virtual axis disposed on the upper surface of the wafer. Accordingly, a virtual line, connecting a first feature region of the measurement unit 520 and a second feature region in the image 530 in which the measurement unit 520 is reflected on the upper surface of the wafer W, may be orthogonal to the upper surface of the wafer W. In this case, the distance Si between the measurement unit 520 and the upper surface of the wafer W may be calculated using a vertical distance from the first feature region of the measurement unit 520 to the upper surface of the wafer W.

Referring to FIGS. 9B and 9C, in the inspection apparatuses 600 and 700 according to an example embodiment, the image capturing devices 610 and 710 may capture an image including at least a portion of the measurement units 620 and 720 and at least a portion of the wafer W. The images 630 and 730, in which the measurement units 620 and 720 are reflected on the upper surface of the wafer W, may overlap at least a portion of the wafer W included in the image captured by the image capturing devices 610 and 710.

In the inspection apparatuses 600 and 700 according to an example embodiment, the measurement units 620 and 720 are spaced apart from an upper portion of a specific location of the wafer, in which a measurement value is to be obtained, by predetermined distances S2 and S3. The specific location may be different from the measurement location on the wafer W in which a measurement value is actually obtained using the measurement units 620 and 720. For example, imaginary lines from the measurement units 620 and 720 to the measurement location on the wafer W may be perpendicular to the wafer W, but may have a predetermined angle other than 90 degrees. For example, the angle may be determined by a tilt or warpage of the upper surface of the wafer W.

However, even when the wafer W is tilted or warpage is present in wafer W, the measurement units 620 and 720 and the images 630 and 730, in which the measurement unit is reflected on the upper surface of the wafer W, may be symmetrical to each other based on a virtual plane. Therefore, similar to the case in which the inspection apparatus 500 according to an example embodiment operates on a normal wafer that is not tilted and does not have warpage, it will be assumed that imaginary lines, connecting first feature regions of the measurement units 620 and 720 and corresponding second feature regions in the images 630 and 730 in which a measurement unit is reflected, are not tilted or are orthogonal to the upper surfaces of the wafers W in which warpage does not occur. In this case, vertical distances from the first feature regions of the measurement units 620 and 720 to the upper surface of the wafer W may be referred to as distances S2 and S3 between the measurement units 620 and 720 and the upper surfaces of the wafers W, respectively.

In the operations of the inspection apparatuses 600 and 700 illustrated in FIGS. 9B and 9C, each of the wafers W may correspond to a tilted wafer or a wafer in which warpage occurs. In example embodiments, the measurement units 620 and 720 may be accurately aligned on the wafer W using images obtained by capturing images of specific regions of the measurement units 620 and 720 and images of the measurement units 620 and 720 reflected on the upper surfaces of the wafer W having mirror surface characteristics, irrespective of the cases in which the wafer W is tilted or warpage occurs in the wafer W. As an example, each of the images obtained by the image capturing devices 610 and 710 may be the same as or similar to the image obtained by the operation of the inspection apparatus 500 according to an example embodiment illustrated in FIG. 9A.

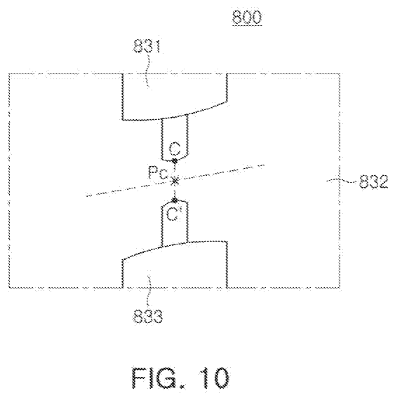

FIG. 10 illustrates an image obtained by the operations of the inspection apparatus in FIGS. 9A to 9C, in the inspection apparatus according to an example embodiment.

Each of the images obtained by the inspection apparatuses 500, 600, and 700 according to example embodiments illustrated in FIGS. 9A to 9C may be the same as or similar to an image 800 illustrated in FIG. 10. However, the image 800 may be slightly different according to image capturing environments such as a tilt of a slope of a wafer, an image capturing angle of an image capturing device, and the like.

An operation of measuring a distance between a measurement unit and an upper surface of a wafer using an inspection apparatus according to an example embodiment may be performed in a manner similar to the above-described example embodiments. Irrespective of whether a wafer is tilted or warpage occurs in the wafer, a distance between a measurement unit and an upper surface of the wafer may be precisely measured using the image 800 obtained by the image capturing device, and the measurement unit may be aligned on the wafer.

Referring to FIG. 10, the image 800 obtained by the image capturing device, included in an inspection apparatus according to an example embodiment, may include a measurement region 831, a wafer region 832, and a reflective region 833, and the like.

According to an example embodiment, the measurement region 831 included in the image 800 may include at least one first feature region C, a reference for measuring a distance between the measurement unit and the upper surface of the wafer. The reflective region 833 may include a second feature region C′ corresponding to the first feature region C included in the measurement region 831.

However, in an actual measurement unit, locations of the first feature region C and the second feature region C′ may be different in each image 800 according to a location of the image capturing device or the measurement unit even when the regions C and C′ correspond to the same region. Therefore, the inspection apparatus according to an example embodiment may use at least one of algorithms such as a pattern matching algorithm, an edge detection algorithm, and an optical character recognition (OCR) algorithm to detect the same first feature region C in each measurement region 831, irrespective of the location of the image capturing device or the measurement unit.

The inspection apparatus according to an example embodiment may measure the distance between the measurement unit and the upper surface of the wafer using the number of pixels between the first feature region C and the second feature region C′ on the image 800. For example, a value obtained by dividing the number of pixels between the first feature region C and the second feature region C′ by 2 may correspond to the distance between the measurement unit and the upper surface of the wafer.

The upper surface of the wafer, a reference surface of an actual distance, may not directly appear on the image 800. As an example, since the reflective region 833 is an image in which the measurement region 831 is reflected on the upper surface of the wafer, the first feature region C and the second feature region C′ may be symmetrical with respect to a virtual axis parallel to the upper surface of the wafer. The virtual axis may be defined as an axis of symmetry and may be one of axes present on the upper surface of the wafer.

In the inspection apparatus according to an example embodiment, the midpoint Pc of a virtual line connecting the first feature region C and the second feature region C′ may be a point on the upper surface of the wafer, and may be a point through which an axis of symmetry passes. Accordingly, the number of pixels between the first feature region C and the midpoint Pc may be equal to a value obtained by dividing the number of pixels between the first feature region C and the second feature region C′ by 2. For example, the number of pixels between the first feature region C and the midpoint Pc may correspond to the distance between the measurement unit and the upper surface of the wafer.

Similarly to the inspection apparatus according to an example embodiment illustrated in FIG. 4B, a relational expression between an actual distance and the number of pixels under corresponding inspection conditions may be obtained in advance to measure a distance between the measurement unit and the upper surface of the wafer, irrespective of the location of the image capturing device or the measurement unit. Even when the operations S110 to S160 illustrated in FIG. 5 are performed to derive a predetermined relational expression, tilting or warping of the upper surface of the wafer may be not cause an error in measuring the distance between the measurement unit and the upper surface of the wafer. Based on a predetermined relational expression, the distance between the measurement unit and the upper surface of the wafer may be measured from the number of pixels between the first feature region C and the second feature region C′ of the image 800.

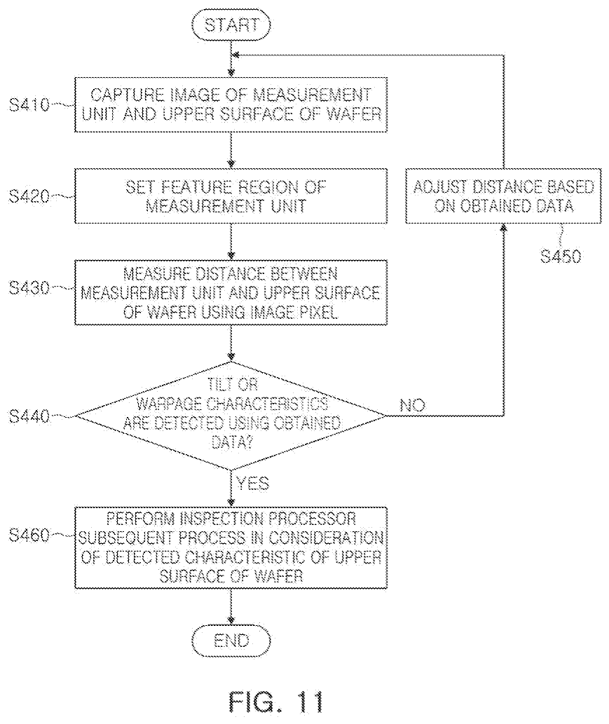

FIG. 11 is a flowchart illustrating a process of detecting a tilt or warpage of a wafer, in an inspection apparatus according to an example embodiment.

Referring to FIG. 11, an inspection apparatus according to an example embodiment may capture at least two or more images, including a measurement unit reflected on an upper surface of a wafer W to detect not only a distance between the measurement unit and the upper surface of the wafer but also a state of the upper surface of the wafer. The state of the upper surface of the wafer may be at least one of a tilt and warpage of the upper surface of the wafer. Therefore, the inspection process may be performed in consideration of the detected state of the upper surface of the wafer.

The inspection apparatus according to an example embodiment may perform operations S410, S420, and S430, respectively corresponding to operations S210, S220, and S230 illustrated in FIG. 7 to detect the state of the upper surface of the wafer. For example, the inspection apparatus may capture an image of the measurement unit and the upper surface of the wafer using an image capturing device (S410), and may set a first feature region of the measurement unit, a reference for measuring a distance in the captured image (S420). In addition, the inspection apparatus may calculate the number of pixels between the first feature region of the measurement region and a second feature region of a reflective region, and may apply the measured number of pixels to the derived predetermined relationship to measure the distance between the measurement unit and the upper surface of the wafer W (S430).

The inspection apparatus may determine whether the tilt or warpage of the wafer can be detected based on distance data measured in operations S410 to S430 (S440). When the tilt or warpage of the wafer cannot be detected in operation S440, at least one of the measurement unit or the wafer may be moved based on the data obtained in the previous operations to adjust a location (S450). Meanwhile, when the tilt or the warpage of the wafer can be detected in S440, the inspection process may be performed in consideration of the detected state of the upper surface of the wafer. For example, the adjustment may be performed by a driving unit.

Since the distance between the measurement unit and the upper surface of the wafer may be measured in at least two points to detect the tilt or warpage of the wafer, operations S410 to S440 may be repeated at least twice. As an example, when a bending change of the upper surface of the wafer is severe due to the warpage of the warpage, operations S410 to S440 may be repeated more times, and the adjustment of the location in operation S450 may be performed in a finer unit.

The operation of detecting the state of the upper surface of the wafer by the inspection apparatus, illustrated in the flowchart of FIG. 11, may be performed separately from an operation of aligning the measurement unit and the wafer according to the example embodiment. However, embodiments are not limited thereto, and the operation of aligning the wafer and the measurement unit by the inspection apparatus and the operation of detecting the state of the upper surface of the wafer may be simultaneously performed to improve the precision of the inspection process.

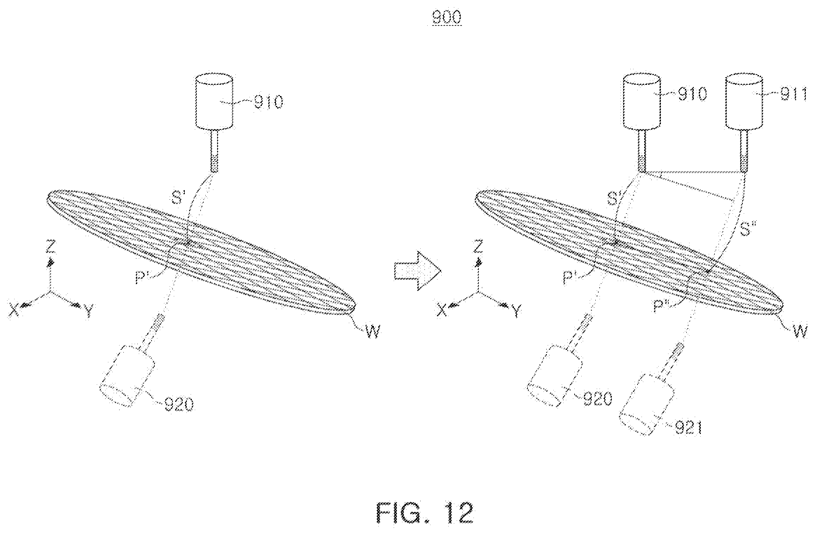

FIG. 12 illustrates a process of detecting a tilt when a wafer has the tilt, in an inspection apparatus according to an example embodiment.

Referring to FIG. 12, an inspection apparatus 900 according to an example embodiment may repeatedly measure distances S′ and S″ between measurement units 910 and 920 and a wafer W having a tilt to measure the tilt of a slope of the wafer W. For example, when the wafer W has a tilt, the measurement unit 910 may be preferentially disposed to be spaced apart from an upper portion of a first location P′ on the wafer W. The inspection apparatus 900 according to an example embodiment may measure the distance S′ between the measurement unit 910 and the upper surfaces of the wafer W using the number of pixels between a first location P′ and a first feature region of a measurement region in an image obtained by an image capturing device.

After measuring the distance S′ between the measurement unit 910 and the upper surface of the wafer W when the measurement unit 910 is disposed to be spaced apart from the upper portion of the first location P′, at least one of the measurement unit 910 and the wafer W may be moved such that the measurement unit 920 is disposed to be spaced apart from an upper portion of the second location P″ on the wafer W. For example, the movement may be performed by a driving unit.

The inspection apparatus 900 according to an example embodiment may appropriately select the second position P″ in consideration of distance data measured in the first location P′ and features of the measurement device and the wafer W. When the second location P″ is selected, not only is the data measured in the first location P′ restrictively considered, but data, obtained by the operation of the inspection apparatus according to the embodiment, may be considered overall.

For example, the measurement unit 920 may be disposed to be spaced apart from the upper portion of the second position P″ on the wafer W. The inspection apparatus 900 according to an example embodiment may measure a distance S″ between the measurement unit 920 and the upper surfaces of the wafers W using the number of pixels between the second location P″ and the first feature region of the measurement region in the image obtained by the image capturing device.

For example, the inspection apparatus 900 according to an example embodiment may measure a distance S′ between the measurement unit 910 and the upper surface of the wafer (W) in the first location P′ and a second distance S″ between the measurement unit 911 and the upper surface of the wafer W in the second location P″. In addition, the inspection apparatus 900 may detect a tilt of a slope of the wafer W between the first location P′ using the measured distances S′ and S″ and a distance between the first location P′ and the second location P″.

As an example, when the distances S′ and S″ have the same value, the inspection apparatus 900 may determine that the wafer W is not tilted. Meanwhile, when the distances S′ and S″ have different values, the inspection apparatus 900 may calculate an angle, at which the wafer W is tilted, using a difference between the distances S′ and S″ and a distance between the first location P′ and the second location P″. As an example, an angle θ indicating a tilting degree of the wafer W may be calculated using Equation 1.

$$θ = arctan \frac{difference between {S}^{′} and {S}^{″}}{distance between {P}^{′} and {P}^{″}} \qquad [ Equation 1 ]$$

Even when warpage is present in the wafer W, warpage of the wafer W may be detected in a similar manner. As an example, the inspection apparatus 900 may measure the distance between the measurement unit 910 and the upper surface of the wafer W in a plurality of locations to estimate warpage present in the wafer W. Therefore, the inspection process may be performed in consideration of the detected tilt or warpage of the wafer W.

As described above, an inspection apparatus according to an example embodiment may capture an image of a measurement unit of a measurement device and an image of a measurement unit reflected on an upper surface of a mirror-treated wafer to generate an image and may more accurately measure a distance between the measurement unit and an upper surface of the wafer using the number of pixels between the measurement unit and the reflected image, based on a feature region of the measurement unit appearing in the generated image. Thus, reliability of measurement may be improved during inspection of a process and spatial resolution required for the measurement device and wafer may be improved.

While example embodiments have been shown and described above, it will be apparent to those skilled in the art that modifications and variations could be made without departing from the scope as defined by the appended claims.

What is claimed is:

1. An inspection apparatus comprising:
a measurement device disposed to be spaced apart from an upper surface of a wafer;
an image capturing device configured to capture an image of at least a portion of the measurement device and at least a portion of the upper surface of the wafer;
a memory storing an algorithm to measure a distance between the measurement device and the upper surface of the wafer based on the image; and
a controller configured to measure the distance between the measurement device and the upper surface of the wafer based on the algorithm,
wherein the image comprises a measurement region in which the measurement device is displayed, a wafer region in which the wafer is displayed, and a reflective region in which the measurement device being reflected on the upper surface of the wafer is displayed, and
wherein the wafer region and the reflective region overlap with each other.

2. The inspection apparatus of claim 1, further comprising:
a driving device configured to move at least one of the measurement device and the wafer based on the distance measured by the controller.

3. The inspection apparatus of claim 1, wherein in the image, the measurement region and the reflective region are symmetrical with respect to a certain location of the wafer region.

4. The inspection apparatus of claim 1, wherein the measurement region comprises at least one first feature region and a reference region to measure the distance between the measurement device and the upper surface of the wafer.

5. The inspection apparatus of claim 4, wherein the at least one first feature region has a form among a point, a line, and a surface.

6. The inspection apparatus of claim 4, wherein a plurality of pixels are present between the at least one first feature region included in the measurement region and at least one second feature region included in a position corresponding to the at least one first feature region of the reflective region, respectively, and
wherein the distance between the measurement device and the upper surface of the wafer is measured based on a number of the plurality of pixels and a predetermined relational expression with respect to the distance between the measurement device and the upper surface of the wafer.

7. The inspection apparatus of claim 4, wherein the measurement of the distance between the measurement device and the upper surface of the wafer based on the at least one first feature region is performed based on at least one of a pattern matching algorithm, an edge detection algorithm, and an optical character recognition (OCR) algorithm.

8. The inspection apparatus of claim 6, wherein the number of the plurality of pixels and the distance have a linear relationship.

9. The inspection apparatus of claim 1, wherein the inspection apparatus is configured to detect a location on the upper surface of the wafer, from which the measurement device is disposed spaced apart, while measuring the distance between the measurement device and the upper surface of the wafer based on the image.

10. The inspection apparatus of claim 1, wherein a location of the measurement device is adjusted to maintain a predetermined spatial resolution with respect to the measurement device and the wafer.

11. The inspection apparatus of claim 10, wherein the distance between the measurement device and the upper surface of the wafer decreases as the predetermined spatial resolution and measurement reliability with respect to the measurement device and the wafer increases.

12. An inspection apparatus comprising:
a probe disposed spaced apart from an upper surface of a wafer;
an image capturing apparatus configured to capture an image of at least a portion of the probe and at least a portion of the upper surface of the wafer;
a memory configured to store an algorithm to detect a location of the probe above the wafer based on the image; and
a controller configured to detect the location of the probe above the wafer based on the image and the algorithm,
wherein the image comprises a first region in which the probe is displayed, a second region in which the wafer is displayed, and a third region in which the probe being reflected on the upper surface of the wafer is displayed, and
wherein at least portions of the first region, the second region, and the third region overlap with each other on the image.

13. An inspection apparatus comprising:
a measurement device disposed above a measuring target;
an image capturing device configured to capture an images of at least a portion of the measurement device and an upper surface of the measuring target in at least two locations, respectively;
a memory storing an algorithm to measure a distance between the measurement device and the upper surface of the measuring target in the at least two locations based on the images; and
a controller configured to measure the distance between the measurement device and the upper surface of the measuring target based on the algorithm and to detect a state of the upper surface of the measuring target in the at least two locations based on the measured distances,
wherein each of the images includes a measurement region in which the measurement device is displayed, a measuring target region in which the measuring target is displayed, and a reflective region in which the measurement device being reflected on the upper surface of the measuring target is displayed, and
wherein the measurement region and the reflective region overlap with each other.

14. The inspection apparatus of claim 13, wherein the state of the upper surface of the measuring target is at least one of a tilt of the upper surface of the measuring target and warpage of the upper surface of the measuring target.

15. The inspection apparatus of claim 13, further comprising:
a driving device configured to move at least one of the measurement device and the measuring target to the at least two locations.

16. The inspection apparatus of claim 15, wherein the driving device is further configured to move at least one of the measurement device and the measuring target based on data obtained by the controller.

17. The inspection apparatus of claim 15, wherein the controller is further configured to detect locations on the upper surface of the measuring target, from which the measurement device is disposed spaced apart, from the images, and
wherein the driving device is further configured to move at least one of the measurement device and the measuring target based on data obtained by the controller.

18. The inspection apparatus of claim 15, wherein the controller is further configured to measure a distance between the measurement device and the upper surface of the measuring target in a first location, and then configured to repeatedly measure a distance between the measurement device and the upper surface of the measuring target in a second location that is different from the first location.

19. The inspection apparatus of claim 13, wherein at least a portion of the measurement region comprises at least one first feature region having an arbitrary form,
wherein a plurality of pixels are present between the at least one first feature region and at least one second feature region included in a location corresponding to the at least one first feature region of the reflective region, respectively, and
wherein the distance is measured based on a predetermined relational expression with respect to the distance between the measurement device and the upper surface of the measuring target.

20. The inspection apparatus of claim 19, wherein the measurement of the distance between the measurement device and the upper surface of the measuring target based on the at least one first feature region and the at least one second feature region is performed based on at least one of a pattern matching algorithm, an edge detection algorithm, and an optical character recognition (OCR) algorithm.
